(19) United States
(12) Patent Application Publication
(10) Pub. No.: US 2024/0319262 A1
(43) Pub. Date: Sep. 26, 2024

(54) Techniques For Testing Input And Output Buffer Circuits Using A Test Bus

(71) Applicant: Altera Corporation, San Jose, CA (US)

(72) Inventors: Pai Ho Bong, Bayan Lepas (MY); Sean Woei Voon, Bukit Mertajam (MY); Ching Sia Lim, Jelutong (MY); Wee Sun Voon, Bayan Lepas (MY)

(73) Assignee: Altera Corporation, San Jose, CA (US)

(21) Appl. No.: 18/736,308

(22) Filed: Jun. 6, 2024

(51) Int. Cl. G01R 31/28; H03K 17/687

(52) U.S. Cl. CPC G01R 31/2884; H03K 17/6871

(57) ABSTRACT

An integrated circuit includes first and second pads, a buffer circuit coupled to the first pad, a first pass gate circuit coupled to the first pad and to the buffer circuit, a second pass gate circuit coupled to the second pad, and a test bus coupled to the first pass gate circuit and the second pass gate circuit. The first pass gate circuit and the second pass gate circuit are configurable to couple the second pad to the buffer circuit through the test bus during a test of the buffer circuit that is performed using the second pad.

### TECHNICAL FIELD

The present disclosure relates to electronic circuits, methods, and systems, and more particularly, to techniques for testing input and output buffer circuits using one or more test busses.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that depicts an example of a testing system for testing input and output (IO) circuit blocks in an integrated circuit.

FIG. 2 is a diagram that depicts an example of each of the pass gate circuits of FIG. 1.

FIG. 3A is a diagram depicting a portion of the testing system of FIG. 1 that is used during tests of the leakage currents from a supply voltage through single-ended output buffer circuits in the integrated circuit (IC).

FIG. 3B is a diagram depicting a portion of the testing system of FIG. 1 that is used during tests of the leakage currents through single-ended output buffer circuits in the integrated circuit (IC) to the ground voltage.

FIG. 3C is a diagram depicting a portion of the testing system of FIG. 1 that is used during tests of the output voltages of two single-ended output buffer circuits in the IC.

FIG. 3D is a diagram depicting a portion of the testing system of FIG. 1 that is used during tests of the differential output voltage of a differential output buffer circuit in the IC.

FIG. 3E is a diagram depicting a portion of the testing system of FIG. 1 that is used during tests of the input voltages of single-ended input buffer circuits in the IC.

FIG. 4 is a diagram of an illustrative example of a configurable integrated circuit (IC).

FIG. 5 illustrates a block diagram of a system that can be used to implement a circuit design to be programmed into a programmable logic device using design software.

FIG. 6 is a diagram that depicts an example of a programmable logic device that includes fabric dies and base dies that are connected to one another via microbumps.

FIG. 7 is a block diagram illustrating a computing system configured to implement one or more aspects of the embodiments described herein.

### DETAILED DESCRIPTION

In many configurable integrated circuits, parametric and leakage tests are performed on input and output pads. According to previously known solutions, testers are used to perform the leakage and parametric test measurements. The input and output pads of the integrated circuits are connected to tester channels for these measurements. The tester requirement limits the number of integrated circuits that can be tested in parallel due to the limited number of tester channels.

To overcome this limitation, non-touch leakage and parametric tests can be implemented in production to remove the need to connect input and output pads to tester channels, which allows many integrated circuits to be tested in parallel with a minimal number of input and output pads connected to tester channels. However, this technique does not meet the testing needs for input and output pads that are coupled to input and output (IO) circuit blocks that support various input and output standards. As an example, a single IO circuit block in a configurable IC can be configured to provide single-ended IO standards, differential IO standards, high speed memory interface IO standards, and others industrial IO standards. The IO circuit blocks can also support a wide voltage range (e.g., from 1 to 3.3 volts).

According to some examples disclosed herein, techniques are provided for testing input and output (IO) circuit blocks in an integrated circuit (IC). The IO circuit blocks include input and output buffer circuits that can support various single-ended and differential IO standards. The input and output buffer circuits are coupled to input and output pads (i.e., external terminals) of the IC. A tester device is coupled to one of the IO circuit blocks in the IC through one or more of the pads. Other IO circuit blocks in the IC can be selectively coupled through pass gates and one or more test busses to the tester device. The pass gates can be selectively turned on and off to test various ones of the IO circuit blocks in the IC. The pass gates can include thick gate transistors that support testing of high voltage analog signals. These techniques do not require that all of the IO circuit blocks or IO pads be coupled to the tester device to perform the tests. In addition, these techniques are low cost and are touchless.

One or more specific examples are described below. In an effort to provide a concise description of these examples, not all features of an actual implementation are described herein. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information (e.g., voltage or current) between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs) and programmable logic devices. As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially fewer configurable features than soft logic or no configurable features.

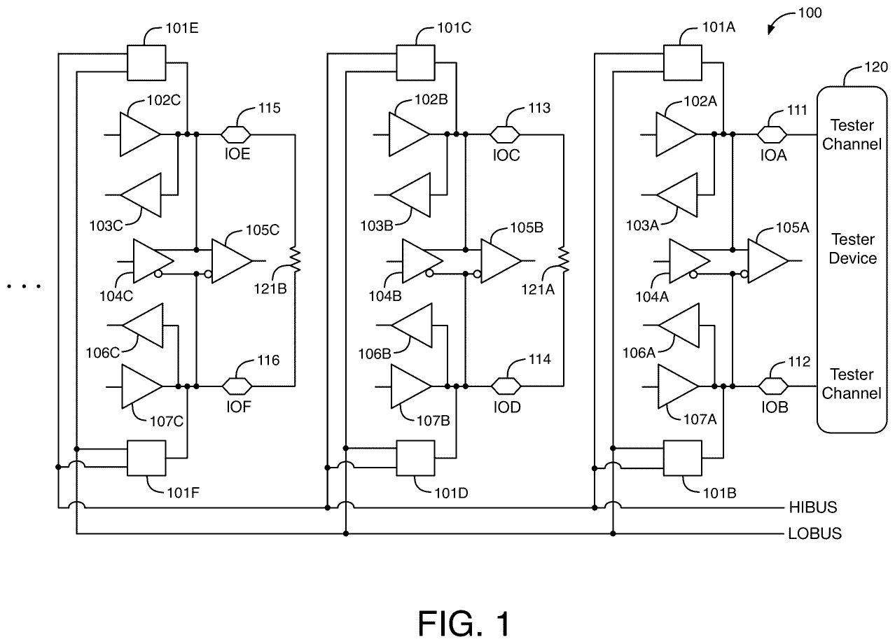

FIG. 1 is a diagram that illustrates an example of a testing system 100 for testing input and output (IO) circuit blocks in an integrated circuit. The testing system 100 includes an integrated circuit (IC) die, at least 2 resistors 121A and 121B, and a tester device 120 that includes 2 tester channels. The resistors 121A-121B and the tester device 120 are outside the IC die. The IC die (also referred to herein simply as an IC) includes at least 6 pass gate circuits 101A-101F (also collectively referred to herein as pass gate circuits 101) and at least 3 input and output (IO) circuit blocks in the example of Figure (FIG. 1. Each of the IO circuit blocks in the IC of FIG. 1 includes two single-ended output buffer circuits 102 and 107, two single-ended input buffer circuits 103 and 106, one differential output buffer circuit 104, one differential input buffer circuit 105, and two conductive input and output (IO) pads. 6 conductive IO pads 111-116 of the IC die are shown in FIG. 1 as an example. The IO pads are external conductive terminals of the IC die. The input buffer circuits are also referred to as receiver circuits, and the output buffer circuits are also referred to as transmitter circuits.

A first one of the IO circuit blocks of FIG. 1 is coupled to tester device 120 through two IO pads 111 (IOA) and 112 (IOB) of the IC. The first one of the IO circuit blocks includes a single-ended output buffer circuit 102A and a single-ended input buffer circuit 103A coupled to pad 111, a single-ended output buffer circuit 107A and a single-ended input buffer circuit 106A coupled to pad 112, a differential output buffer circuit 104A coupled to pads 111-112, and a differential input buffer circuit 105A coupled to pads 111-112.

A second one of the IO circuit blocks shown in FIG. 1 includes a single-ended output buffer circuit 102B and a single-ended input buffer circuit 103B that are coupled to pad 113 of the IC, a single-ended output buffer circuit 107B and a single-ended input buffer circuit 106B that are coupled to pad 114 of the IC, a differential output buffer circuit 104B coupled to pads 113-114, and a differential input buffer circuit 105B coupled to pads 113-114. Resistor 121A is coupled between pads 113 (IOC) and 114 (IOD) of the IC. A third one of the IO circuit blocks shown in FIG. 1 includes a single-ended output buffer circuit 102C and a single-ended input buffer circuit 103C that are coupled to pad 115, a single-ended output buffer circuit 107C and a single-ended input buffer circuit 106C that are coupled to pad 116, a differential output buffer circuit 104C coupled to pads 115-116, and a differential input buffer circuit 105C coupled to pads 115-116. Resistor 121B is coupled between pads 115 (IOE) and 116 (IOF) of the IC.

Three IO circuit blocks are shown in FIG. 1 merely as an example. According to various examples, an IC implementing techniques disclosed herein can include any number of IO circuit blocks (e.g., 2, 3, 4, 5, 6, etc. IO circuit blocks) coupled to the tester device 120, as illustrated by the ellipse in FIG. 1. In addition, an IC implementing techniques disclosed herein can include any number of input and/or output buffer circuits in each IO circuit block that are tested using a tester device. The circuitry in the IC of FIG. 1 can be fabricated in any type of integrated circuit (IC) device, such as a configurable logic IC (e.g., a field programmable gate array or FPGA), a microprocessor IC, a graphics processing unit IC, a transceiver IC, a memory IC, an application specific integrated circuit (ASIC), or a structured ASIC.

The testing system 100 of FIG. 1 provides a single non-touch testing architecture that is able to test all combinations of input and output (IO) standards and voltages in a configurable logic IC, such as a field programmable gate array (FPGA), or other type of IC. The testing system 100 supports a wide voltage range of test voltages (e.g., from 1 volt up to 3.3 volts). The testing system 100 can be used to test both single-ended and differential IO buffer circuits to determine if IO specifications are satisfied.

The testing system 100 provides a low tester channel count in the tester device 120 that can be used for low pad count integrated circuits (ICs) and low cost tester devices. The testing system 100 also allows parallel testing of multiple IC dies on a high pad count tester device 120. The testing system 100 also enables reduction in the cost of testing IO circuit blocks and reduction in the amount of tester hardware.

The testing system 100 can be used as a low cost solution that does not require design-for-test circuitry, such as analog-to-digital converters, comparators, counters, or high sampling clock signals. The testing system 100 can be used for testing leakage currents in IO buffer circuits, IO voltage output specifications, IO voltage input specifications, and pull-up and pull-down resistances in IO circuit blocks. Because the IO circuit blocks of FIG. 1 can be accessed through the tester device 120, the testing system 100 provides better measurement accuracy than on-die testers having intrinsic offset errors.

The IC of FIG. 1 also includes a first analog test bus HIBUS for transmitting a high voltage, and a second analog test bus LOBUS for transmitting a low voltage. The pass gates 101A, 101B, 101C, 101D, 101E, and 101F are coupled between pads 111, 112, 113, 114, 115, and 116, respectively, and the HIBUS and LOBUS busses. The test bus HIBUS is used for providing a high voltage (e.g., above 1.8 volts) for testing the IO circuit blocks. The test bus LOBUS is used for providing a low voltage (e.g., less than 1.8 volts) for testing the IO circuit blocks.

The first one of the IO circuit blocks (including buffer circuits 102A-107A) is the only IO circuit block shown in FIG. 1 that is connected directly to tester device 120 through pads 111-112. The other IO circuit blocks of FIG. 1 can be coupled to tester device 120 through test bus HIBUS or LOBUS by selectively turning on corresponding ones of the pass gate circuits 101. The tester device 120 can test any of the input or output buffer circuits in the second, third, etc. IO circuit blocks of FIG. 1 by applying or sensing a test voltage or current through at least one of pads 111 or 112, through selected ones of the pass gates 101, and through the test bus HIBUS and/or LOBUS. The tester device 120 then evaluates the resulting voltage or current at pad 111 or 112 to determine a result.

Each of the IO circuit blocks in FIG. 1 is coupled to two of the pass gate circuits 101. Each of the pass gate circuits 101 includes thick gate transistors that are coupled to the two common test buses HIBUS and LOBUS. The thick gate transistors are selected to support high voltages on the test busses HIBUS and LOBUS.

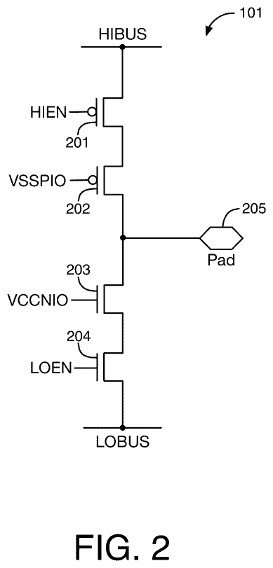

FIG. 2 is a diagram that depicts a pass gate circuit 101 that is an example of each of the pass gate circuits of FIG. 1. According to the example of FIG. 2, each of the pass gate circuits 101A-101F shown in FIG. 1, and each of the other pass gate circuits 101 not shown in FIG. 1, has the architecture shown in FIG. 2. In the example of FIG. 2, the pass gate circuit 101 is a double-stacked pass gate circuit having 4 thick gate field-effect transistors (FETs) 201-204. The pass gate circuit 101 includes 2 p-channel FETs 201-202 and 2 n-channel FETs 203-204 that are coupled in series between the analog test bus HIBUS and the analog test bus LOBUS. Also, the drains of transistors 202-203 are coupled to a pad 205.

Two bias voltages VSSPIO and VCCNIO are provided to the gates of the transistors 202 and 203, respectively, so that the pass gate circuit 101 can operate in a wide voltage range without any electrical overstress (EOS) issues. A first enable signal HIEN is provided to the gate of p-channel FET 201, and a second enable signal LOEN is provided to the gate of n-channel FET 204.

The pass gate circuit 101 of FIG. 2 can be configured to couple the analog test bus HIBUS to the pad 205 by generating a low voltage in enable signal HIEN that turns p-channel FET 201 on and by generating a low voltage in enable signal LOEN that turns n-channel FET 204 off. The bias voltage VSSPIO provided to the gate of p-channel FET 202 is set to a low voltage that causes p-channel FET 202 to be on. When FETs 201-202 are on, test bus HIBUS is coupled to pad 205 through FETs 201-202, allowing current flow between HIBUS and pad 205. Because n-channel FET 204 is off, the analog test bus LOBUS is decoupled from the pad 205 and from bus HIBUS.

The pass gate circuit 101 can also be configured to couple the analog test bus LOBUS to pad 205 by generating a high voltage in enable signal LOEN that turns n-channel FET 204 on and by generating a high voltage in enable signal HIEN that turns p-channel FET 201 off. The bias voltage VCCNIO provided to the gate of n-channel FET 203 is set to a high voltage that causes n-channel FET 203 to be on. When FETs 203-204 are on, test bus LOBUS is coupled to pad 205 through FETs 203-204, allowing current flow between LOBUS and pad 205. Because p-channel FET 201 is off, the analog test bus HIBUS is decoupled from pad 205 and from test bus LOBUS.

The pass gate circuit 101 can, as examples, be controlled using an FPGA configuration circuit, such as a configuration shift register (CSR) or other storage circuit, that generates the enable signals HIEN and LOEN. An external resistor can be connected to the pad 205 and to another IO pad within an IO pair of pads. Any IO pair of pads can be tested at any time by properly configuring the respective pass gate circuits 101.

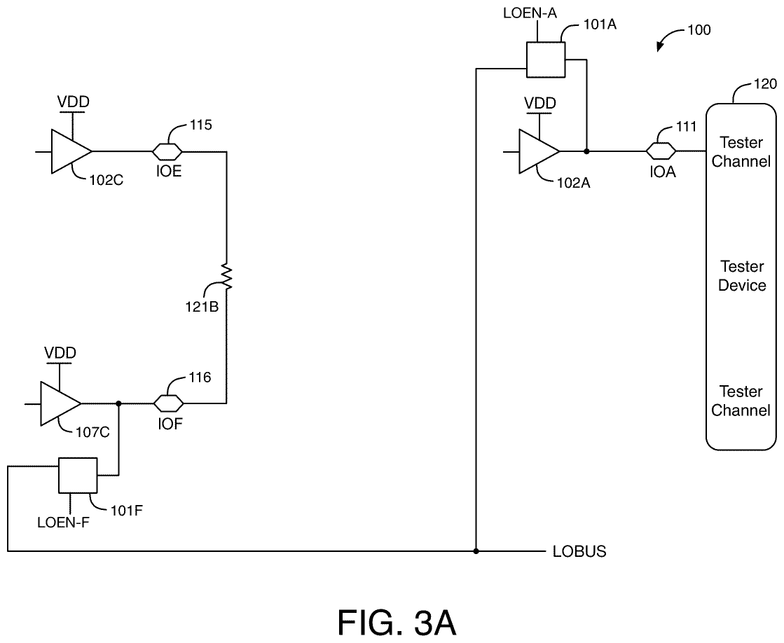

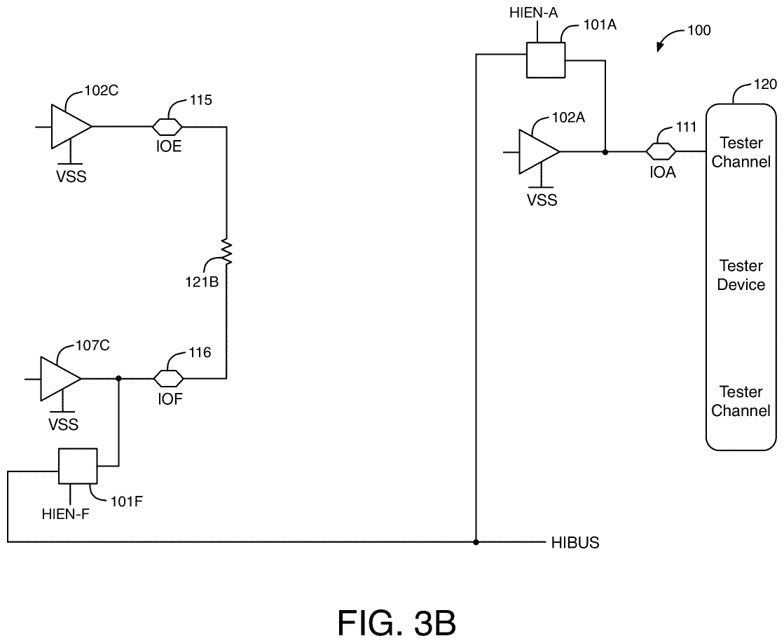

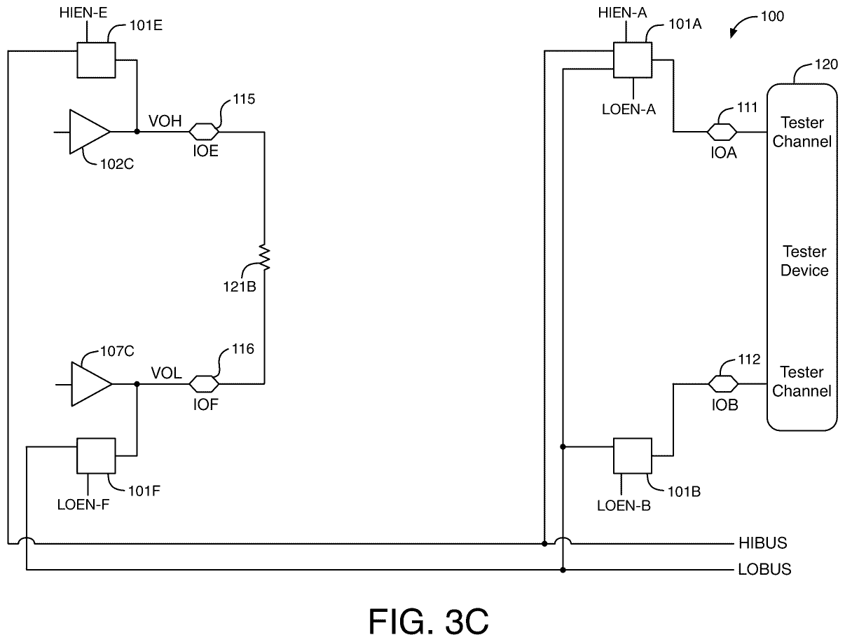

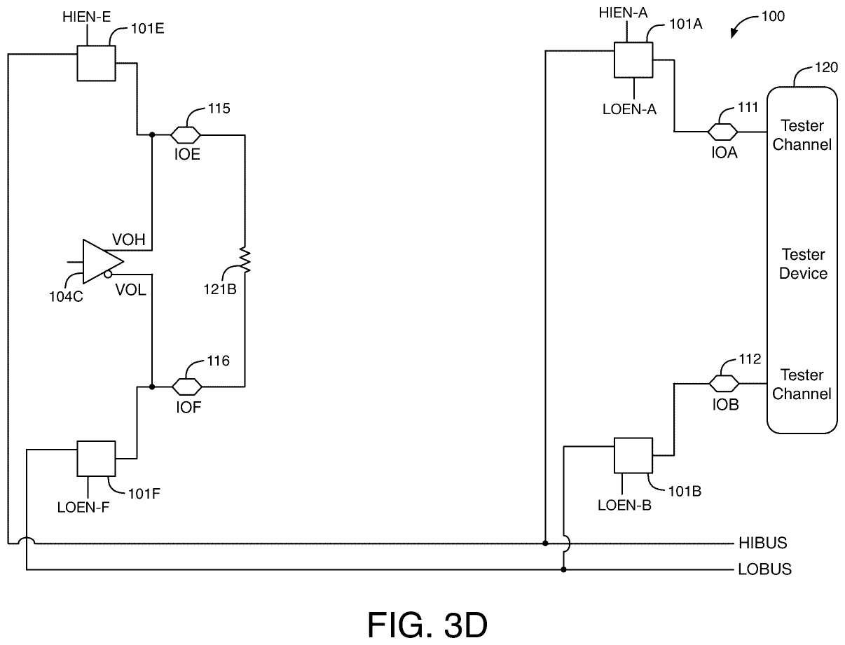

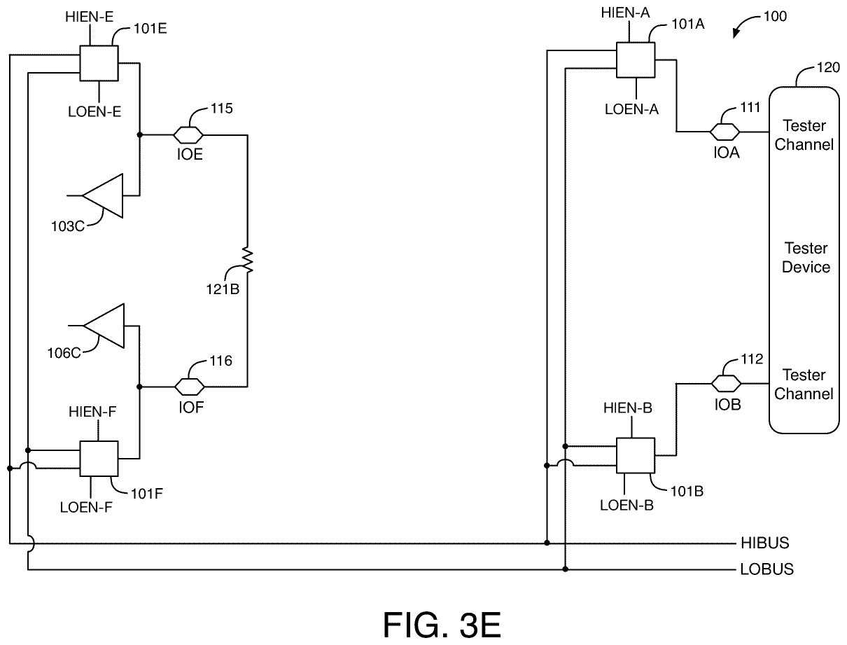

FIG. 3A is a diagram depicting a portion of the testing system 100 of FIG. 1 that is used during tests of the leakage currents from a supply voltage VDD through single-ended output buffer circuits in the integrated circuit (IC). Figure (FIG. 3A illustrates the tester device 120, pass gate circuits 101A and 101F, resistor 121B, pads 111 and 115-116, and single-ended output buffer circuits 102A, 102C, and 107C. Only the portion of the testing system 100 that is used to test leakage currents from the supply voltage VDD through the output buffer circuits 102A, 102C, and 107C is shown in FIG. 3A.

To test the leakage currents from supply voltage VDD through the output buffer circuits 102A, 102C, and 107C, the pass gate circuits 101A and 101F are turned on to couple pads 111 and 116, respectively, to the analog test bus LOBUS. An enable signal LOEN-A that is provided to the gate of the n-channel FET 204 in pass gate circuit 101A is asserted to a high voltage that turns FET 204 on in pass gate circuit 101A. The p-channel FET 201 in pass gate circuit 101A is off. As a result, the pad 111 is coupled through pass gate circuit 101A to the analog test bus LOBUS. An enable signal LOEN-F that is provided to the gate of the n-channel FET 204 in pass gate circuit 101F is asserted to a high voltage to turn FET 204 on in pass gate circuit 101F. The p-channel FET 201 in pass gate circuit 101F is off. As a result, the pad 116 is coupled through pass gate circuit 101F to the analog test bus LOBUS.

When the pass gate circuits 101A and 101F couple pads 111 and 116 to test bus LOBUS, the tester device 120 applies a low voltage (e.g., 0 volts) to pad 111 (IOA) at the first tester channel to measure the leakage currents from supply voltage VDD through the single-ended output buffer circuits 102A, 102C, and 107C. Each of the output buffer circuits 102A, 102C, and 107C is coupled to a node at the supply voltage VDD as shown in FIG. 3A through a pull-up circuit path. The output of output buffer circuit 102C is coupled to the test bus LOBUS through pad 115, resistor 121B, pad 116, and pass gate circuit 101F. The output of output buffer circuit 107C is coupled to the test bus LOBUS through pass gate circuit 101F. Each of the input and output buffer circuits 102-107 coupled to the IO pads in the IO circuit blocks of FIG. 1 are disabled and off during the tests of the leakage currents from VDD that are disclosed herein with respect to FIG. 3A, except that the targeted output buffer circuit 107C is enabled but not driving an output signal (i.e., the output buffer circuit 107C is tri-stated).

During a test, leakage currents can flow from a node at supply voltage VDD through output buffer circuit 107C, from a node at supply voltage VDD through output buffer circuit 102C, and from a node at supply voltage VDD through output buffer circuit 102A. The pass gate circuit 101F couples the test bus LOBUS to pad 116. The total current received at tester device 120 through pad 111 is based on the leakage current through output buffer circuit 102A and the leakage currents through output buffer circuits 102C and 107C that affect the voltage and/or current in test bus LOBUS, which is coupled to pad 111 through pass gate circuit 101A. The tester device 120 measures the total current received from the IC through pad 111. Because the measured total current through pad 111 is based on the leakage currents from three leakage paths through output buffer circuits 102A, 102C, and 107C, the tester device 120 can deduct the leakage currents through output buffer circuits 102A and 102C from the total leakage current received through pad 111 to determine the leakage current through output buffer circuit 107C.

FIG. 3B is a diagram depicting a portion of the testing system 100 of FIG. 1 that is used during tests of the leakage currents through single-ended output buffer circuits in the integrated circuit (IC) to a ground voltage VSS. FIG. 3B depicts tester device 120, pass gate circuits 101A and 101F, resistor 121B, pads 111 and 115-116, and single-ended output buffer circuits 102A, 102C, and 107C. Only the portion of the testing system 100 that is used to test leakage currents to voltage VSS through the output buffer circuits 102A, 102C, and 107C is shown in FIG. 3B. Tests of the leakage currents of output buffer circuits 102A, 102C, and 107C are described herein as examples with respect to FIGS. 3A-3B. According to other examples, tests can be performed to test leakage currents of any buffer circuits that can be coupled to one of the test busses through the pass gate circuits 101.

To test the leakage currents through output buffer circuits 102A, 102C, and 107C to voltage VSS, pass gate circuits 101A and 101F are turned on to couple pads 111 and 116, respectively, to analog test bus HIBUS. An enable signal HIEN-A that is provided to the gate of the p-channel FET 201 in pass gate circuit 101A is asserted to a low voltage that turns FET 201 on in pass gate circuit 101A. The n-channel FET 204 in pass gate circuit 101A is off. As a result, the pad 111 is coupled through pass gate circuit 101A to the analog test bus HIBUS. An enable signal HIEN-F that is provided to the gate of the p-channel FET 201 in pass gate circuit 101F is asserted to a low voltage that turns FET 201 on in pass gate circuit 101F. The n-channel FET 204 in pass gate circuit 101F is off. As a result, pad 116 is coupled through pass gate circuit 101F to analog test bus HIBUS.

When the pass gate circuits 101A and 101F couple pads 111 and 116 to test bus HIBUS, tester device 120 applies the supply voltage VDD to pad 111 (IOA) at the first tester channel to measure the leakage currents through the single-ended output buffer circuits 102A, 102C, and 107C to nodes at voltage VSS. Each of the output buffer circuits 102A, 102C, and 107C is coupled to a node at the ground voltage VSS as shown in FIG. 3B through a pull-down circuit path. The output of output buffer circuit 102C is coupled to the test bus HIBUS through pad 115, resistor 121B, pad 116, and pass gate circuit 101F. The output of output buffer circuit 107C is coupled to the test bus HIBUS through pass gate circuit 101F. Each of the input and output buffer circuits 102-107 coupled to the IO pads in the IO circuit blocks of FIG. 1 are disabled and off during the tests of the leakage currents that are disclosed herein with respect to FIG. 3B, except that the targeted output buffer circuit 107C is enabled but not driving an output signal (i.e., the output buffer circuit 107C is tri-stated).

During a test, the voltage VDD applied to node 111 can cause leakage current to flow through output buffer circuit 102A to a node at voltage VSS. Because nodes 115-116 are coupled to node 111 through pass gate circuits 101A and 101F and test bus HIBUS, and node 111 is at voltage VDD, voltages are generated at nodes 115 and 116 that can cause leakage currents through output buffer circuits 102C and 107C, respectively, to nodes at voltage VSS. The tester device 120 measures the total current provided to the IC through pad 111. Because the total current measured includes leakage currents of three leakage paths through output buffer circuits 102A, 102C, and 107C, tester device 120 can deduct the leakage currents through output buffer circuits 102A and 102C from the total current provided to pad 111 to determine the leakage current through output buffer circuit 107C.

FIG. 3C is a diagram depicting a portion of the testing system 100 of FIG. 1 that is used during tests of the output voltages of two single-ended output buffer circuits in the IC. FIG. 3C illustrates the tester device 120, pass gate circuits 101A-101B and 101E-101F, resistor 121B, pads 111-112 and 115-116, and single-ended output buffer circuits 102C and 107C. Only the portion of the testing system 100 that is used to test the output voltages of output buffer circuits 102C and 107C is shown in FIG. 3C. Tests of the high and low output voltages of output buffer circuits 102C and 107C are described below as examples with respect to FIG. 3C. According to other examples, tests can be performed on any output or input voltages of any buffer circuits that can be coupled to one of the test busses through the pass gate circuits.

To test the high output voltage VOH of output buffer circuit 102C, pass gate circuits 101A and 101E are turned on to couple pads 111 and 115, respectively, to analog test bus HIBUS. The enable signal HIEN-A is asserted to a low voltage that turns FET 201 on in pass gate circuit 101A, and the n-channel FET 204 in pass gate circuit 101A is off. As a result, the pad 111 is coupled through pass gate circuit 101A to test bus HIBUS. An enable signal HIEN-E provided to the gate of the p-channel FET 201 in pass gate circuit 101E is asserted to a low voltage that turns FET 201 on in pass gate circuit 101E, and the n-channel FET 204 in pass gate circuit 101E is off. As a result, pad 115 is coupled through pass gate circuit 101E to test bus HIBUS.

During a test of the high output voltage VOH of output buffer circuit 102C, the pass gate circuit 101E couples the output of output buffer circuit 102C to test bus HIBUS, and the pass gate circuit 101A couples test bus HIBUS to tester device 120 through pad 111. During this test, the output buffer circuit 102C drives a high voltage VOH to pad 115. The other input and output buffer circuits 102-107 coupled to the IO pads in the IO circuit blocks of FIG. 1 are disabled during the test, except that a concurrent test of another output buffer circuit can be performed through test bus LOBUS, as described below. The tester device 120 senses the high voltage VOH at the tester channel coupled to pad 111 through the test bus HIBUS and pass gate circuits 101A and 101E.

The low output voltage VOL of output buffer circuit 107C can be tested concurrently with a test of the high output voltage VOH of output buffer circuit 102C, or in a non-overlapping time interval before or after a test of the high output voltage VOH of output buffer circuit 102C. During a test of the low output voltage VOL of output buffer circuit 107C in a non-overlapping time interval before or after a test of the high output voltage VOH of output buffer circuit 102C, pass gate circuits 101A and 101F can be turned on to couple pads 111 and 116, respectively, to test bus LOBUS. The enable signal LOEN-A is asserted to a high voltage to turn FET 204 on in pass gate circuit 101A, and the p-channel FET 201 in pass gate circuit 101A is off. As a result, the pad 111 is coupled through pass gate circuit 101A to the analog test bus LOBUS. The enable signal LOEN-F is asserted to a high voltage to turn FET 204 on in pass gate circuit 101F, and the p-channel FET 201 in pass gate circuit 101F is off. As a result, the pad 116 is coupled through pass gate circuit 101F to the analog test bus LOBUS.

During this test of the low output voltage VOL of output buffer circuit 107C, the pass gate circuit 101F couples the output of output buffer circuit 107C to test bus LOBUS, and the pass gate circuit 101A couples test bus LOBUS to tester device 120 through pad 111. During this test, the output buffer circuit 107C drives a low voltage VOL to pad 116. The other input and output buffer circuits 102-107 coupled to the IO pads in the IO circuit blocks of FIG. 1 are disabled during this test. The tester device 120 senses the low voltage VOL at the tester channel coupled to pad 111 through pass gate circuit 101A, the test bus LOBUS, and pass gate circuit 101F.

During a test of the low output voltage VOL of output buffer circuit 107C that is performed during a time interval that is at least partly concurrent with a test of the high output voltage VOH of output buffer circuit 102C, pass gate circuits 101B and 101F are turned on to couple pads 112 and 116, respectively, to test bus LOBUS. An enable signal LOEN-B provided to the gate of the n-channel FET 204 in pass gate circuit 101B is asserted to a high voltage that turns FET 204 in pass gate circuit 101B on, and the p-channel FET 201 in pass gate circuit 101B is off. As a result, the pad 112 is coupled through pass gate circuit 101B to test bus LOBUS. The enable signal LOEN-F is asserted to a high voltage that turns FET 204 on in pass gate circuit 101F, and the p-channel FET 201 in pass gate circuit 101F is off. As a result, the pad 116 is coupled through pass gate circuit 101F to test bus LOBUS. During this test, output buffer circuit 107C drives a low output voltage VOL to pad 116, and tester device 120 senses the low output voltage VOL at the tester channel coupled to pad 112 through pass gate circuit 101B, test bus LOBUS, and pass gate circuit 101F.

The tester device 120 can include software or hardware that calculates the current IOX through resistor 121B based on the voltages VOH and VOL determined using the tests described above and using the equation IOX=(VOH−VOL)/R121B, where R121B is the resistance of resistor 121B. The tester device 120 can determine the resistance RDN of output buffer circuit 107C using the equation RDN=VOL/IOX. The tester device 120 can also determine the resistance of output buffer circuit 102C using the equation RUP=(VCCN−VOH)/IOX, wherein VCCN is the supply voltage that the output buffer circuit 102C uses to generate voltage VOH.

FIG. 3D is a diagram depicting a portion of the testing system 100 of FIG. 1 that is used during a test of the differential output voltage of a differential output buffer circuit in the IC. FIG. 3D illustrates the tester device 120, pass gate circuits 101A-101B and 101E-101F, resistor 121B, pads 111-112 and 115-116, and different output buffer circuit 104C. Only the portion of the testing system 100 that is used to test the differential output voltage of differential output buffer circuit 104C is shown in FIG. 3D. A test of the output voltage of output buffer circuit 104C is described below with respect to FIG. 3D as an example. According to other examples, tests can be performed on any output or input voltages of any buffer circuits that can be coupled to at least one of the test busses through the pass gate circuits.

In the example of FIG. 3D, the output voltages VOH and VOL of differential output buffer circuit 104C are tested concurrently through busses HIBUS and LOBUS. The differential output voltage VOD of output buffer circuit 104C is VOD=VOH−VOL. To test the high output voltage VOH of output buffer circuit 104C, pass gate circuits 101A and 101E are turned on to couple pads 111 and 115, respectively, to analog test bus HIBUS, as described above with respect to FIG. 3C. To test the low output voltage VOL of output buffer circuit 104C, pass gate circuits 101B and 101F are turned on to couple pads 112 and 116, respectively, to analog test bus LOBUS, as described above with respect to FIG. 3C.

During a test of the output voltages VOH and VOL of output buffer circuit 104C, the pass gate circuits 101B and 101F couple the output of output buffer circuit 104C that generates low voltage VOL to pad 112 through test bus LOBUS, and the pass gate circuits 101A and 101E couple the output of output buffer circuit 104C that generates high voltage VOH to pad 111 through test bus HIBUS. During this test, output buffer circuit 104C drives the high and low voltages VOH and VOL to pads 115 and 116, respectively. The other input and output buffer circuits 102-107 coupled to the IO pads in the IO circuit blocks of FIG. 1 are disabled during this test. The tester device 120 senses the voltages VOH and VOL at the tester channels coupled to pads 111-112 through the test busses HIBUS and LOBUS, respectively, and the pass gate circuits.

FIG. 3E is a diagram depicting a portion of the testing system 100 of FIG. 1 that is used during tests of the input voltages of single-ended input buffer circuits in the IC. FIG. 3E illustrates the tester device 120, pass gate circuits 101A-101B and 101E-101F, resistor 121B, pads 111-112 and 115-116, and single-ended input buffer circuits 103C and 106C. Only the portion of the testing system 100 that is used to test the input voltages of buffer circuits 103C and 106C is shown in the example of FIG. 3E. According to other examples, tests can be performed on any output or input voltages of any buffer circuits that can be coupled to one of the test busses.

According to one implementation of the testing system 100, pass gate circuits 101A and 101F are turned on by asserting enable signals HIEN-A and HIEN-F to couple pads 111 and 116, respectively, to analog test bus HIBUS to perform a test of the high input voltage VIH of input buffer circuit 106C. Input buffer circuit 106C is decoupled from LOBUS. During this test, the tester device 120 applies the high input voltage VIH to the input buffer circuit 106C through pad 111, pass gate circuit 101A, test bus HIBUS, and pass gate circuit 101F.

According to another implementation of the testing system 100, pass gate circuits 101A and 101F are turned on by asserting enable signals LOEN-A and LOEN-F to couple pads 111 and 116, respectively, to analog test bus LOBUS to perform a test of the low input voltage VIL of input buffer circuit 106C. Input buffer circuit 106C is decoupled from HIBUS. During this test, the tester device 120 applies the low input voltage VIL to the input buffer circuit 106C through pad 111, pass gate circuit 101A, test bus LOBUS, and pass gate circuit 101F.

According to yet another implementation of the testing system 100, pass gate circuits 101A and 101E are turned on by asserting enable signals HIEN-A and HIEN-E to couple pads 111 and 115, respectively, to analog test bus HIBUS to perform a test of the high input voltage VIH of input buffer circuit 103C. Input buffer circuit 103C is decoupled from LOBUS. During this test, the tester device 120 applies the high input voltage VIH to the input buffer circuit 103C through pad 111, pass gate circuit 101A, test bus HIBUS, and pass gate circuit 101E.

According to still another implementation of the testing system 100, pass gate circuits 101A and 101E are turned on by asserting enable signals LOEN-A and LOEN-E to couple pads 111 and 115, respectively, to analog test bus LOBUS to perform a test of the low input voltage VIL of input buffer circuit 103C. Input buffer circuit 103C is decoupled from HIBUS. During this test, the tester device 120 applies the low input voltage VIL to the input buffer circuit 103C through pad 111, pass gate circuit 101A, test bus LOBUS, and pass gate circuit 101E.

According to other implementations of the testing system 100, the pass gate circuit 101B can be turned on to test input buffer circuits 103C and/or 106C. For example, pass gate circuits 101B and 101E can be turned on to provide a high voltage VIH or a low voltage VIL from tester device 120 through analog test bus HIBUS or LOBUS, respectively, during a test of input buffer circuit 103C. As another example, pass gate circuits 101B and 101F can be turned on to provide a high voltage VIH or a low voltage VIL from tester device 120 through analog test bus HIBUS or LOBUS, respectively, during a test of input buffer circuit 106C. Other input buffer circuits in the IC can also be tested using these techniques.

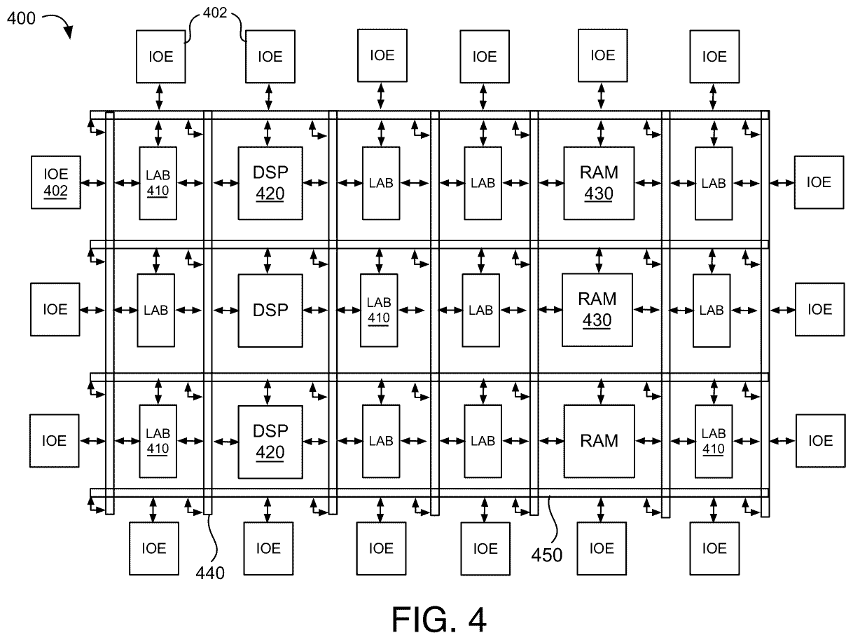

FIG. 4 is a diagram of an illustrative example of a configurable integrated circuit (IC) 400. Configurable IC 400 is an example of an IC that can include the IO circuit blocks, analog test busses, pads, and pass gate circuits disclosed herein with respect to FIGS. 1-2 and 3A-3E. As shown in FIG. 4, the configurable integrated circuit 400 includes a two-dimensional array of configurable logic circuit blocks, including logic array blocks (LABs) 410 and other configurable logic circuit blocks, such as random access memory (RAM) blocks 430 and digital signal processing (DSP) blocks 420, for example. Configurable logic circuit blocks, such as LABs 410, can include smaller configurable regions (e.g., configurable logic elements, configurable logic blocks, or adaptive logic modules (ALMs)) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 (e.g., including IO circuit blocks) for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400).

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

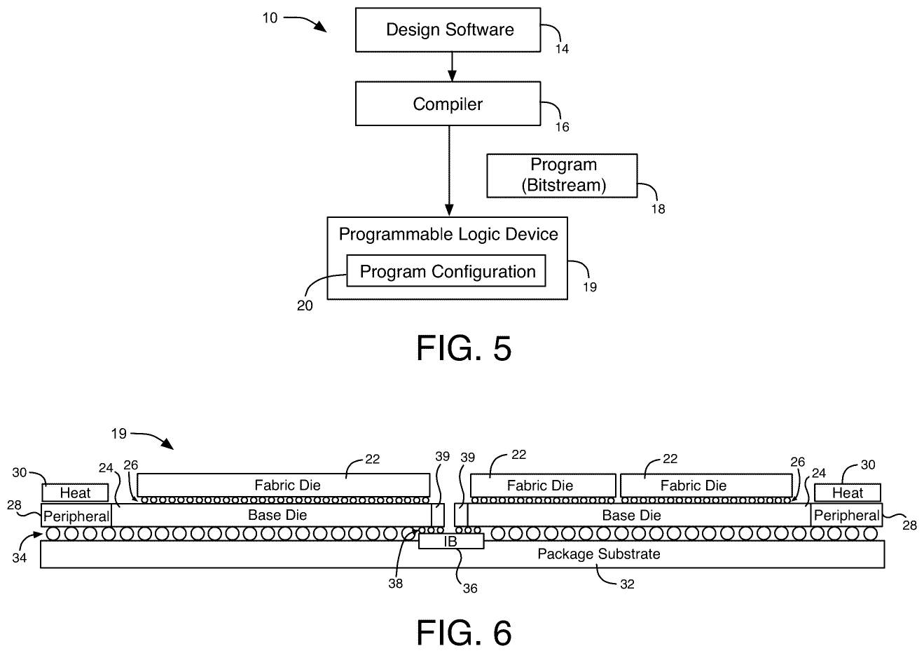

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

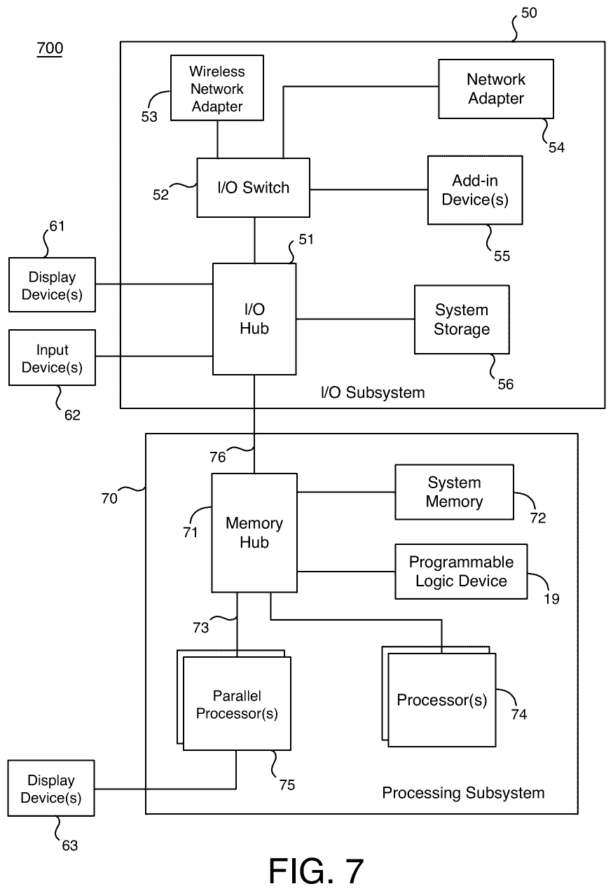

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising: first and second pads; a first buffer circuit coupled to the first pad; a first pass gate circuit coupled to the first pad and to the first buffer circuit; a second pass gate circuit coupled to the second pad; and a first test bus coupled to the first pass gate circuit and to the second pass gate circuit, wherein the first pass gate circuit and the second pass gate circuit are configurable to couple the second pad to the first buffer circuit through the first test bus during a first test of the first buffer circuit that is performed using the second pad.

In Example 2, the integrated circuit of Example 1 further comprises: a second test bus coupled to the first pass gate circuit and to the second pass gate circuit, wherein the first pass gate circuit and the second pass gate circuit are configurable to couple the second pad to the first buffer circuit through the second test bus during a second test of one of an input voltage, an output voltage, or a leakage current of the first buffer circuit performed using the second pad.

In Example 3, the integrated circuit of any one of Examples 1-2 further comprises: a third pad; a second buffer circuit coupled to the third pad; and a third pass gate circuit coupled to the third pad and to the second buffer circuit, wherein the first test bus is coupled to the third pass gate circuit, and wherein the second pass gate circuit and the third pass gate circuit are configurable to couple the second buffer circuit to the second pad through the first test bus during a second test of an input voltage, an output voltage, or a leakage current of the second buffer circuit performed using the second pad.

In Example 4, the integrated circuit of Example 3 further comprises: a second test bus coupled to the second pass gate circuit and to the third pass gate circuit, wherein the second pass gate circuit and the third pass gate circuit are configurable to couple the second buffer circuit to the second pad through the second test bus during a third test of the second buffer circuit performed using the second test bus.

In Example 5, the integrated circuit of Example 4 further comprises: a third differential buffer circuit coupled to the first pad and to the third pad, wherein the second pass gate circuit and the third pass gate circuit are configurable to couple the third differential buffer circuit to the second pad through the second test bus during a fourth test of the third differential buffer circuit performed using the second pad.

In Example 6, the integrated circuit of Example 5 can optionally include, wherein the first pass gate circuit and the second pass gate circuit are configurable to couple the third differential buffer circuit to a fourth pad of the integrated circuit through the first test bus during the fourth test performed using the fourth pad.

In Example 7, the integrated circuit of any one of Examples 2 or 4-6 can optionally include, wherein the second pass gate circuit comprises first transistors coupled between the first test bus and the second pad and second transistors coupled between the second pad and the second test bus.

In Example 8, the integrated circuit of any one of Examples 1-7 further comprises: a third pad coupled to the first buffer circuit; a third pass gate circuit coupled to the third pad; and a second test bus coupled to the second pass gate circuit and to the third pass gate circuit, wherein the second pass gate circuit and the third pass gate circuit are configurable to couple the first buffer circuit to the second pad through the second test bus during a second test of the first buffer circuit performed using the second test bus.

In Example 9, the integrated circuit of any one of Examples 1-8 can optionally include, wherein the first pass gate circuit and the second pass gate circuit are configurable to couple the second pad to the first buffer circuit through the first test bus during the first test of one of an input voltage, an output voltage, or a leakage current of the first buffer circuit that is performed using the second pad.

Example 10 is a method for testing a first buffer circuit in an integrated circuit, the method comprising: coupling a first pad of the integrated circuit to a first test bus in the integrated circuit through a first pass gate circuit in the integrated circuit; coupling the first test bus to the first buffer circuit through a second pass gate circuit in the integrated circuit, wherein the first buffer circuit is coupled to a second pad of the integrated circuit; and providing a first signal through the second pass gate circuit, the first test bus, the first pass gate circuit, and the first pad to test the first buffer circuit.

In Example 11, the method of Example 10 further comprises: coupling a third pad of the integrated circuit to a second test bus in the integrated circuit through a third pass gate circuit in the integrated circuit; coupling the second test bus to the first buffer circuit through a fourth pass gate circuit in the integrated circuit; and providing a second signal through the third pass gate circuit, the second test bus, the fourth pass gate circuit, and the third pad to test one of an input voltage, an output voltage, or a leakage current of the first buffer circuit.

In Example 12, the method of any one of Examples 10-11 further comprises: coupling the first test bus to a second buffer circuit in the integrated circuit through a third pass gate circuit in the integrated circuit, wherein the second buffer circuit is coupled to a third pad of the integrated circuit; and providing a second signal through the first pad, the first pass gate circuit, the first test bus, and the third pass gate circuit to test the second buffer circuit.

In Example 13, the method of any one of Examples 10-12 further comprises: coupling the first pad to a second test bus in the integrated circuit through the first pass gate circuit; coupling the second test bus to a second buffer circuit in the integrated circuit through a third pass gate circuit in the integrated circuit, wherein the second buffer circuit is coupled to a third pad of the integrated circuit; and providing a second signal through the first pad, the first pass gate circuit, the second test bus, and the third pass gate circuit to test the second buffer circuit.

In Example 14, the method of any one of Examples 10-13 further comprises: coupling a third pad of the integrated circuit to a second test bus in the integrated circuit through a third pass gate circuit in the integrated circuit; coupling the second test bus to a second buffer circuit in the integrated circuit through a fourth pass gate circuit in the integrated circuit, wherein the second buffer circuit is coupled to a fourth pad of the integrated circuit; and providing a second signal through the third pad, the third pass gate circuit, the second test bus, and the fourth pass gate circuit to test the second buffer circuit.

In Example 15, the method of any one of Examples 10-14 can optionally include, wherein providing the first signal through the second pass gate circuit, the first test bus, the first pass gate circuit, and the first pad to test the first buffer circuit comprises testing an input voltage, an output voltage, or a leakage current of the first buffer circuit using the second pass gate circuit, the first test bus, the first pass gate circuit, and the first pad.

Example 16 is a testing system comprising: a tester device; and an integrated circuit comprising a first pad, an input and output circuit block coupled to the first pad, a first test bus, a second pad coupled to the tester device, a first pass gate circuit coupled between the second pad and the first test bus, and a second pass gate circuit coupled between the first test bus and the input and output circuit block, wherein the first pass gate circuit and the second pass gate circuit are configurable to couple the input and output circuit block to the second pad through the first test bus during a first test of the input and output circuit block using the tester device.

In Example 17, the testing system of Example 16 can optionally include, wherein an input voltage, an output voltage, or a leakage current of a buffer circuit in the input and output circuit block is tested using the first test bus during the first test.

In Example 18, the testing system of any one of Examples 16-17 can optionally include, wherein the integrated circuit further comprises a second test bus and a third pass gate circuit coupled between the second test bus and the input and output circuit block, and wherein the first pass gate circuit and the third pass gate circuit are configurable to couple the input and output circuit block to the second pad through the second test bus during a second test of the input and output circuit block using the tester device.

In Example 19, the testing system of any one of Examples 16-18 can optionally include, wherein the integrated circuit further comprises a third pad coupled to the tester device and a third pass gate circuit coupled between the first test bus and the third pad, and wherein the third pass gate circuit and the second pass gate circuit are configurable to couple the input and output circuit block to the third pad through the first test bus during a second test of the input and output circuit block using the tester device.

In Example 20, the testing system of any one of Examples 16-19 can optionally include, wherein the input and output circuit block comprises an input buffer circuit and an output buffer circuit that are coupled to the first pad, and wherein the first test is performed on the input buffer circuit or on the output buffer circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
first and second pads;
a first buffer circuit coupled to the first pad;
a first pass gate circuit coupled to the first pad and to the first buffer circuit;
a second pass gate circuit coupled to the second pad; and
a first test bus coupled to the first pass gate circuit and to the second pass gate circuit, wherein the first pass gate circuit and the second pass gate circuit are configurable to couple the second pad to the first buffer circuit through the first test bus during a first test of the first buffer circuit that is performed using the second pad.

2. The integrated circuit of claim 1 further comprising:
a second test bus coupled to the first pass gate circuit and to the second pass gate circuit, wherein the first pass gate circuit and the second pass gate circuit are configurable to couple the second pad to the first buffer circuit through the second test bus during a second test of one of an input voltage, an output voltage, or a leakage current of the first buffer circuit performed using the second pad.

3. The integrated circuit of claim 1 further comprising:
a third pad;
a second buffer circuit coupled to the third pad; and
a third pass gate circuit coupled to the third pad and to the second buffer circuit, wherein the first test bus is coupled to the third pass gate circuit, and wherein the second pass gate circuit and the third pass gate circuit are configurable to couple the second buffer circuit to the second pad through the first test bus during a second test of an input voltage, an output voltage, or a leakage current of the second buffer circuit performed using the second pad.

4. The integrated circuit of claim 3 further comprising:
a second test bus coupled to the second pass gate circuit and to the third pass gate circuit, wherein the second pass gate circuit and the third pass gate circuit are configurable to couple the second buffer circuit to the second pad through the second test bus during a third test of the second buffer circuit performed using the second test bus.

5. The integrated circuit of claim 4 further comprising:
a third differential buffer circuit coupled to the first pad and to the third pad, wherein the second pass gate circuit and the third pass gate circuit are configurable to couple the third differential buffer circuit to the second pad through the second test bus during a fourth test of the third differential buffer circuit performed using the second pad.

6. The integrated circuit of claim 5, wherein the first pass gate circuit and the second pass gate circuit are configurable to couple the third differential buffer circuit to a fourth pad of the integrated circuit through the first test bus during the fourth test performed using the fourth pad.

7. The integrated circuit of claim 2, wherein the second pass gate circuit comprises first transistors coupled between the first test bus and the second pad and second transistors coupled between the second pad and the second test bus.

8. The integrated circuit of claim 1 further comprising:
a third pad coupled to the first buffer circuit;
a third pass gate circuit coupled to the third pad; and
a second test bus coupled to the second pass gate circuit and to the third pass gate circuit, wherein the second pass gate circuit and the third pass gate circuit are configurable to couple the first buffer circuit to the second pad through the second test bus during a second test of the first buffer circuit performed using the second test bus.

9. The integrated circuit of claim 1, wherein the first pass gate circuit and the second pass gate circuit are configurable to couple the second pad to the first buffer circuit through the first test bus during the first test of one of an input voltage, an output voltage, or a leakage current of the first buffer circuit that is performed using the second pad.

10. A method for testing a first buffer circuit in an integrated circuit, the method comprising:
coupling a first pad of the integrated circuit to a first test bus in the integrated circuit through a first pass gate circuit in the integrated circuit;
coupling the first test bus to the first buffer circuit through a second pass gate circuit in the integrated circuit, wherein the first buffer circuit is coupled to a second pad of the integrated circuit; and
providing a first signal through the second pass gate circuit, the first test bus, the first pass gate circuit, and the first pad to test the first buffer circuit.

11. The method of claim 10 further comprising:
coupling a third pad of the integrated circuit to a second test bus in the integrated circuit through a third pass gate circuit in the integrated circuit;
coupling the second test bus to the first buffer circuit through a fourth pass gate circuit in the integrated circuit; and
providing a second signal through the third pass gate circuit, the second test bus, the fourth pass gate circuit, and the third pad to test one of an input voltage, an output voltage, or a leakage current of the first buffer circuit.

12. The method of claim 10 further comprising:
coupling the first test bus to a second buffer circuit in the integrated circuit through a third pass gate circuit in the integrated circuit, wherein the second buffer circuit is coupled to a third pad of the integrated circuit; and
providing a second signal through the first pad, the first pass gate circuit, the first test bus, and the third pass gate circuit to test the second buffer circuit.

13. The method of claim 10 further comprising:
coupling the first pad to a second test bus in the integrated circuit through the first pass gate circuit;
coupling the second test bus to a second buffer circuit in the integrated circuit through a third pass gate circuit in the integrated circuit, wherein the second buffer circuit is coupled to a third pad of the integrated circuit; and
providing a second signal through the first pad, the first pass gate circuit, the second test bus, and the third pass gate circuit to test the second buffer circuit.

14. The method of claim 10 further comprising:
coupling a third pad of the integrated circuit to a second test bus in the integrated circuit through a third pass gate circuit in the integrated circuit;
coupling the second test bus to a second buffer circuit in the integrated circuit through a fourth pass gate circuit in the integrated circuit, wherein the second buffer circuit is coupled to a fourth pad of the integrated circuit; and
providing a second signal through the third pad, the third pass gate circuit, the second test bus, and the fourth pass gate circuit to test the second buffer circuit.

15. The method of claim 10, wherein providing the first signal through the second pass gate circuit, the first test bus, the first pass gate circuit, and the first pad to test the first buffer circuit comprises testing an input voltage, an output voltage, or a leakage current of the first buffer circuit using the second pass gate circuit, the first test bus, the first pass gate circuit, and the first pad.

16. A testing system comprising:
a tester device; and
an integrated circuit comprising a first pad, an input and output circuit block coupled to the first pad, a first test bus, a second pad coupled to the tester device, a first pass gate circuit coupled between the second pad and the first test bus, and a second pass gate circuit coupled between the first test bus and the input and output circuit block, wherein the first pass gate circuit and the second pass gate circuit are configurable to couple the input and output circuit block to the second pad through the first test bus during a first test of the input and output circuit block using the tester device.

17. The testing system of claim 16, wherein an input voltage, an output voltage, or a leakage current of a buffer circuit in the input and output circuit block is tested using the first test bus during the first test.

18. The testing system of claim 16, wherein the integrated circuit further comprises a second test bus and a third pass gate circuit coupled between the second test bus and the input and output circuit block, and wherein the first pass gate circuit and the third pass gate circuit are configurable to couple the input and output circuit block to the second pad through the second test bus during a second test of the input and output circuit block using the tester device.

19. The testing system of claim 16, wherein the integrated circuit further comprises a third pad coupled to the tester device and a third pass gate circuit coupled between the first test bus and the third pad, and wherein the third pass gate circuit and the second pass gate circuit are configurable to couple the input and output circuit block to the third pad through the first test bus during a second test of the input and output circuit block using the tester device.

20. The testing system of claim 16, wherein the input and output circuit block comprises an input buffer circuit and an output buffer circuit that are coupled to the first pad, and wherein the first test is performed on the input buffer circuit or on the output buffer circuit.
